(19) United States
(12) Patent Application Publication
(10) Pub. No.: US 2005/0173678 A1
(43) Pub. Date: Aug. 11, 2005

(54) Surface treatment agents for metal films of printed circuit boards

(75) Inventors: Ichiro Miura, Iruma-shi (JP); Kazutaka Nakanami, Iruma-shi (JP); Yoshitou Hayashida, Iruma-shi (JP); Takao Ohno, Iruma-shi (JP)

Correspondence Address: OLIFF & BERRIDGE, PLC, P.O. BOX 19928, ALEXANDRIA, VA, 22320, US

(73) Assignee: TAMURA KAKEN CORPORATION, Iruma-shi (JP)

(21) Appl. No.: 11/036,366

(22) Filed: Jan. 18, 2005

(30) Foreign Application Priority Data
Feb. 10, 2004 (JP) P2004-032854

(51) Int. Cl. C09K 3/00; H05K 1/18

(52) U.S. Cl. 252/394; 361/748

(57) ABSTRACT

A surface treatment agent is applied onto a metal film of a printed circuit board to form a rust preventive film. The surface treatment agent for metal comprises an aqueous solution comprising an organic acid having a boiling point of 170° C. or higher and one or more compound selected from the group consisting of an imidazole based compound and a benzimidazole based compound.

This application claims the benefit of Japanese Patent Application P 2004-32854, filed on Feb. 10, 2004, the entirety of which is incorporated by reference.

The present invention relates to a surface treatment agent for metal, a printed circuit board, and a surface treatment method for metal of a printed circuit board.

A printed circuit board is adapted so that one circuit unit can be formed by forming a pattern of circuit wiring on, for example, a copper-clad lamination and mounting an electronic part thereon. As such a printed circuit board, a surface-mounted type is frequently adapted, wherein a circuit pattern having a circuit wiring is provided on the surface of the printed circuit board, and the electronic part is mounted on the circuit pattern. To mount a chip part having electrodes at both ends thereof as such an electronic part, for example, a flux is applied to the printed circuit board, and the chip part is then soldered by means of jet soldering or reflow soldering. To pattern-form the circuit of the printed circuit board, the copper foil portion of the copper-clad lamination is etched so as to provide a desired circuit wiring, and the resulting circuit is coated with a solder resist film while leaving the part for soldering the chip part of the resulting circuit (the part of a so-called soldering land) followed by soft etching.

Although the chip part may be soldered immediately after forming the circuit pattern, the process up to the coating with the solder resist film and the following soldering process are, in general, performed independently. For example, after a printed circuit board coated with the solder resist film is once stored as a part, the soldering process of the chip part is carried out. Alternatively, after the printed circuit board coated with the solder resist film is distributed as a part, another agent may carry out the soldering process. In such a case, since a lot of time might pass until the soldering process is carried out, the exposed copper foil surface of the soldering land is easily air-oxidized. In a humid atmosphere, particularly, oxidation of the copper foil surface tends to take place. Therefore, in order to prevent the oxidation of the copper foil surface, formation of an antioxidant film is carried out, and a surface protective agent is used therefor.

Even in the case of using the printed circuit board coated with the solder resist film before long from its production, when double-face mounting electronic parts, for example, by the reflow soldering method, a high-temperature heating of 260° C. or the like is carried out after applying a solder paste to the soldering land in order to melt the solder powder. Therefore, during the soldering process to one side of the printed circuit board, the other side is also exposed to such a high temperature, which facilitates the oxidation of the copper foil surface of the soldering land. Accordingly, the treatment for forming the antioxidant film is also carried out in this case.

In both the cases of the treatment with the surface protective agent and the antioxidant treatment of the soldering land of the other side for preventing the heat deterioration caused according to the soldering process of one side of the printed circuit board, a so-called preflux is used. Particularly, a water-soluble preflux using no organic solvent and having no risk of environmental pollution or fire is preferentially used. Conventionally, the copper foil of the exposed soldering land is subjected to a rust preventive treatment, and it is known to use a water-soluble surface protective agent for printed wiring board containing a benzimidazole-based compound as the water-soluble preflux, as described in Japanese Patent Application Laid-Open Nos. 5-25407 and 5-186888. In case of a preflux containing rosin or the like, its coating film is formed also in other than the copper foil, and high circuit reliability cannot be obtained unless the coating film is washed after component mounting. In contrast to this, according to methods described in Japanese Patent Application Laid-Open Nos. 5-25407 and 5-186888, a printed board with a circuit pattern of copper foil formed on the surface is dipped in a water-soluble printed wiring board surface protective agent, whereby a heat resisting film is formed on the copper and copper alloy surface of the circuit pattern of the printed circuit board. This resisting film also has satisfactory moisture resistance even after exposed to high humidity and is excellent in the protecting property of the printed circuit board and the solderability in component mounting. Since it is not necessary to remove the rosin coating film by washing, these methods are excellent in productivity, performance and the like.

Since imidazole-based compound and benzimidazole-based compound which are main components of this printed wiring board surface protective agent are generally insoluble to water, they are made soluble by using, as a solubilizing agent for forming their water-soluble salts, an inorganic acid such as hydrochloric acid or phosphoric acid, or an organic acid such as acetic acid, oxalic acid or p-toluene sulfonic acid (Japanese Patent Application Laid-Open No. 7-243053).

In recent years, a surface mounting method is being frequently adapted as the connection method of an electronic part to a printed wiring board, and the printed wiring board becomes exposed to a high temperature due to temporary fixing of a chip part, double-face mounting of parts and devices, mixed mounting of a chip part and a discrete part, or the like.

Therefore, a water-soluble preflux is used. However, since an organic acid having a low boiling point is used in such a water-soluble preflux, which is scattered to the circumference during use, there were concerns of odor, deterioration of working environments, and scattering of an organic acid compound to the atmosphere. Further, it was also found that the evaporation of the organic acid causes a compositional change of the solution, resulting in crystallization of the imidazole compound or fluctuation of the solution physical property, which is apt to cause a reduction in film forming property. In this case, since the film physical property is changed, the production yield of the printed wiring board is reduced.

The present invention thus has an object to provide a surface treatment agent capable of reducing the scattering of an organic acid compound to the atmosphere to prevent the fluctuation of film physical property due to the compositional change of solution, while preventing the loss of stability by temperature change or the like with high heat resistance and moisture resistance of the coating and excellent solderability in component mounting.

As a result of the earnest studies to solve the above problems, the present inventors have found that a metal-surface treatment agent comprising an aqueous solution containing, as essential components, an imidazole-based compound or benzimidazole-based compound and an organic acid having a boiling point of 170° C. or higher can solve the problem, and thus provides a novel water-soluble preflux.

The present invention also relates to a printed circuit board characterized by providing a rust preventive film formed by applying the above-mentioned surface treatment agent.

The present invention further relates to a surface treatment method for metal of a printed circuit board characterized by applying the above-mentioned surface treatment agent onto a metal film of a printed circuit board, thereby forming a rust preventive film.

The present inventors found that, in case of using an imidazole compound or benzimidazole compound as a main component of a metal-surface treatment agent, an organic acid compound having a boiling point of 170° C. or higher is used as its solubilizing agent, whereby the heat resistance and moisture resistance of the coating can be kept high while reducing the scattering of the organic acid to the atmosphere to prevent the fluctuation of the film physical property due to the compositional change of the solution, and excellent solderability in component mounting can be provided to prevent the loss of stability by temperature change or the like.

Since the imidazole-based compound or benzimidazole-based compound is hardly soluble to neutral water, it is water-solubilized by use of the organic acid having a boiling point of 170° C. or higher in the present invention. At this time, a water-soluble organic solvent may be used in combination.

These and other objects, features and advantages of the invention will be appreciated upon reading the following description of the invention when taken in conjunction with the attached drawings, with the understanding that some modifications, variations and changes of the same could be made by the skilled person in the art.

### BRIEF DESCRIPTION OF THE DRAWINGS

FIG. 1 shows the temperature profile of an air reflow furnace used in the heat resistance test of water-soluble preflux coatings.

### PREFERRED EMBODIMENTS OF THE INVENTION

The boiling point of the organic acid used in the present invention is 170° C. or higher, but it is further preferably set to 200° C. or higher. Although the upper limit of the boiling point of the organic acid is not particularly defined, it can be set to, for example, 270° C. or lower since the water solubility of the organic acid tends to decrease as the boiling point increases.

As the organic acid used in the present invention, the following ones are particularly preferred.

(1) Monovalent Saturated Fatty Acid Having 5 or more Carbon Atoms

The number of carbon atoms is preferably, for example, 7 or less although the upper limit is not particularly defined.

(2) Monovalent Unsaturated Fatty Acid Having 5 or more Carbon Atoms

The number of carbon atoms is preferably, for example, 7 or less although the upper limit is not particularly defined.

(3) Divalent Fatty Acid

The number of carbon atoms is preferably, for example, 8 or less although the upper limit is not particularly defined.

(4) Alkoxy Fatty Acid

Although the alkoxy group thereof is not particularly limited, an alkoxy group having 1-4 carbon atoms such as methoxy, ethoxy, propoxy, or butoxy group can be exemplified. The fatty acid moiety may be either a saturated fatty acid or an unsaturated fatty acid. The number of carbon atoms of the fatty acid side is particularly preferably 1-3 although it is not particularly limited.

(5) Hydroxy Fatty Acid

The fatty acid moiety may be either a saturated fatty acid or an unsaturated fatty acid. The number of carbon atoms of the fatty acid side is particularly preferably 1-6 although it is not particularly limited.

(6) Keto Fatty Acid

The fatty acid moiety may be either a saturated fatty acid or an unsaturated fatty acid. The number of carbon atoms of the fatty acid side is particularly preferably 3-7 although it is not particularly limited.

(7) Sulfonic Acid

The fatty acid moiety may be a saturated fatty acid, an unsaturated fatty acid, or an aromatic fatty acid. The number of carbon atoms of the fatty acid side is particularly preferably 3-8 although it is not particularly limited. A fatty acid having a substituted or non-substituted benzene ring is preferably used, and as the substituent of the benzene ring, an alkyl group such as methyl or ethyl group is preferred.

The organic acid particularly preferably has no hydroxy group. Concrete examples of the organic acid having no hydroxy group include oxalic acid, malonic acid, succinic acid, adipic acid, maleic acid, fumaric acid, p-toluene sulfonic acid, methane sulfonic acid, methoxy acetic acid, and levulinic acid. Methoxy acetic acid and levulinic acid are particularly preferred.

The content of the organic acid in the surface treatment agent of the present invention is particularly preferably 1-40 wt % although it is not limited. As a water-soluble organic solvent usable in combination therewith, methanol, ethanol, acetone and the like can be given. The content of the water-soluble organic solvent in the surface treatment agent is particularly preferably 1-10 wt % although it is not limited.

Although the imidazole-based compound or benzimidazole-based compound suitable to the execution of the present invention is not limited, imidazoles shown in the following chemical formulae 1-6 are particularly preferred. 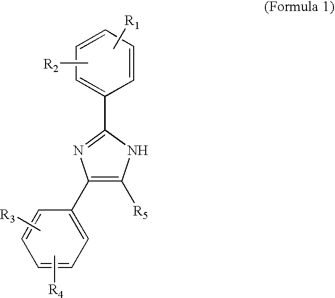
(wherein R₁, R₂, R₃ and R₄ each represents hydrogen, a linear or branched alkyl group having 1-7 carbon atoms, a halogen atom, a hydroxy group, or a lower alkoxy group (preferably having 1 to 4 carbon atoms). R₅ represents hydrogen or a linear or branched alkyl group having 1-11 carbon atoms or halogen-substituted linear or branched alkyl group having 1-11 carbon atoms.) 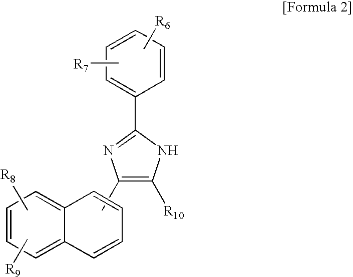
(wherein R₆, R₇, R₈ and R₉ each represents hydrogen, a linear or branched alkyl group having 1-7 carbon atoms, a halogen atom, a hydroxy group, or a lower alkoxy group (preferably having 1 to 4 carbon atoms). R₁₀ represents hydrogen or a linear or branched alkyl group having 1-11 carbon atoms or halogen-atom substituted linear or branched alkyl group having 1-11 carbon atoms.) 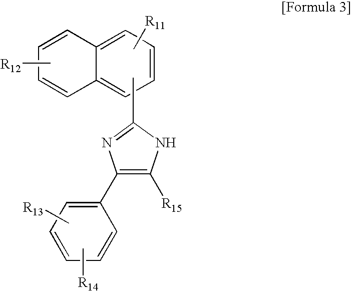
(wherein R₁₁, R₁₂, R₁₃ and R₁₄ each represents hydrogen, a linear or branched alkyl group having 1-7 carbon atoms, a halogen atom, a hydroxy group, or a lower alkoxy group (preferably having 1 to 4 carbon atoms). R₁₅ represents hydrogen or a linear or branched alkyl group having 1-11 carbon atoms or halogen atom-substituted linear or branched alkyl group having 1-11 carbon atoms.) 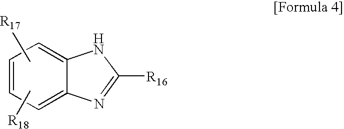
(wherein R₁₆ represents a linear or branched alkyl group having 5-11 carbon atoms or halogen- or alkoxy group-substituted alkyl group having 5-11 carbon atoms. R₁₇ and R₁₈ each represents hydrogen, a linear or branched alkyl group having 1-7 carbon atoms, a halogen atom, a hydroxyl group, or a lower alkoxy group (preferably having 1 to 4 carbon atoms).) 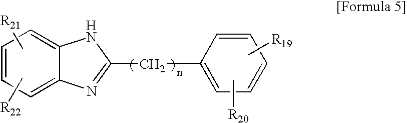
(wherein R₁₉ and R₂₀ each represents hydrogen, a linear or branched alkyl group or halogen- or alkoxy group-substituted alkyl group having 1-7 carbon atoms, a halogen atom, a hydroxy group, or a lower alkoxy group (preferably having 1 to 4 carbon atoms). R₂₁ and R₂₂ each represents hydrogen, a linear or branched alkyl group having 1-7 carbon atoms, a halogen atom, a hydroxy group, or a lower alkoxy group (preferably having 1 to 4 carbon atoms).) 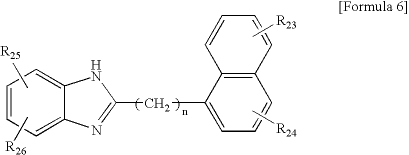
(wherein n represents an integer of 1-10. R₂₃ and R₂₄ each represents hydrogen, a linear or branched alkyl group or halogen- or alkoxy group-substituted alkyl group having 1-7 carbon atoms, a halogen atom, a hydroxy group, or a lower alkoxy group (preferably having 1 to 4 carbon atoms). R₂₅ and R₂₆ each represents hydrogen, a linear or branched alkyl group having 1-7 carbon atoms, a halogen atom, a hydroxy group or a lower alkoxy group (preferably having 1 to 4 carbon atoms).)

The imidazole based compound includes all the compounds having imidazole ring. Typical examples of the imidazole-based compound suitable for the execution of the present invention include 2,4-diphenyl-1H-imidazole, 5-butyl-2,4-diphenyl-1H-imidazole, 5-hexyl-2,4-diphenyl-1H-imidazole, 5-ethylhexyl-2,4-diphenyl-1H-imidazole, 5-octyl-2,4-diphenyl-1H-imidazole, 5-butyl-4-naphthalene-1-yl-2-phenyl-1H-imidazole, 5-hexyl-4-haphthalene-1-yl-2-phenyl-1H-imidazole, 5-ethylhexyl-4-naphthalene-1-yl-2-phenyl-1H-imidazole, 5-octyl-4-naphthalene-1-yl-2-phenyl-1H-imidazole, 5-(2-bromobutyl)-2,4-diphenyl-1H-imidazole, 5-(2-bromobutyl)-4-naphthalene-1-yl-2-phenyl-1H-imidazole, 5-hexyl-4-phenyl-2-toluyl-1H-imidazole, 5-hexyl-2-phenyl-4-toluyl-1H-imidazole, 4-(4-bromophenyl)-5-hexyl-2-phenyl-1H-imidazole, 2-(4-bromophenyl)-5-hexyl-4-phenyl-1H-imidazole, 4-(5-hexyl-2-phenyl-1H-imidazole-4-yl)-phenol, 4-(5-hexyl-4-phenyl-1H-imidazole-2-yl)-phenol, 4-(4-bromophenyl)-5-butyl-2-phenyl-1H-imidazole, 2-(4-bromophenyl)-5-butyl-4-phenyl-1H-imidazole, 5-hexyl-4-(3-methyl-naphthalene-1-yl)-2-phenyl-1H-imidazole, 5-hexyl-4-(4-methoxy-phenyl)-2-phenyl-1H-imidazole, 5-hexyl-2-(4-methoxy-phenyl)-4-naphthalene-1-yl-1H-imidazole, 5-hexyl-2-naphthalene-1-yl-4-phenyl-1H-imidazole and the like.

The benzimidazole based compound includes all the compounds having benzimidazole ring. Typical examples of the benzimidazole-based compound include 2-phenyl-methylbenzimidazole, 2-phenyl-dimethylbenzimidazole, 2-tosyl-methylbenzimidazole, 2-tosyl-dimethylbenzimidazole, 2-xylyl-methylbenzimidazole, 2-xylyl-dimethylbenzimidazole, 2-mesityl-methylbenzimidazole, 2-mesityl-dimethylbenzimidazole, 2-(8-phenyloctyl)benzimidazole, 2-benzylbenzimidazole, 2-naphthalene-1-yl-methyl-benzimidazole, 5,6-dimethyl-2-(2-phenylethyl)benzimidazole, 4-chloro-2-(3-phenylpropyl)benzimidazole, 6-dimethylamino-2-(9-phenylnonyl)benzimidazole, 4,7-dihydroxy-2-benzylbenzimidazole, 4-sial-2-(6-phenylhexyl)benzimidazole, 5,6-dinitro-2-benzylbenzimidazole, 4,7-diethoxy-2-(2-phenylethyl)benzimidazole, 6-amino-2-(4-phenylbutyl)benzimidazole, 6-acetyl-2-benzylbenzimidazole, 4-benzoyl-2-(5-phenylpentyl)benzimidazole, 6-carbamoyl-2-(7-phenylheptyl)benzimidazole, 6-ethoxycarbonyl-2-benzylbenzimidazole, 4,5,6-trimethoxy-2-(2-phenylethyl)benzimidazole, 5,6-dimethyl-7-benzoyl-2-(3-phenylpropyl)benzimidazole, 4,5-dichloro-6-n-butyl-2-(9-phenylnonyl)benzimidazole, 4-fluoro-6-formyl-2-benylbenzimidazole, 6-carbamoyl-5-ethoxy-2-(10-phenyldecyl)benzimidazole, 5,6-dimethyl-2-{(4-methoxyphenyl)butyl}benzimidazole, 6-chloro-2-{(2-nitrophenyl)ethyl}benzimidazole, 6-carboethoxy-2-(3-bromobenzyl)benzimidazole, 4-hydroxy-2-{(4-cyanophenyl)propyl}benzimidazole, 6-dimethylamino-2-{(4-formylphenyl)propyl}benzimidazole, 6-benzoyl-2-{(4-tert-butylphenyl)ethyl}benzimidazole, 2-{(2-acetylphenyl)pentyl}benzimidazole, 6-carbamoyl-2-{(2,4-dihydroxyphenyl)ethyl}benzimidazole, 2-(8-phenyloctyl)benzimidazole, 5,6-dimethyl-2-(2-phenylethyl)benzimidazole, 4-chloro-2-(3-phenylpropyl)benzimidazole, 6-dimethylamino-2-(9-phenylnonyl)benzimidazole, 4,7-dihydroxy-2-benzylbenzimidazole, 4-sial-2-(6-phenylhexyl)benzimidazole, 5,6-dinitro-2-benzylbenzimidazole, 4,7-diethoxy-2-(2-phenylethyl)benzimidazole, 6-amino-2-(4-phenylbutyl)benzimidazole, 6-acetyl-2-benzylbenzimidazole, 4-benzoyl-2-(5-phenylpentyl)benzimidazole, 6-carbamoyl-2-(7-phenylheptyl)benzimidazole, 6-ethoxycarbonyl-2-benzylbenzimidazole, 4,5,6-trimethoxy-2-(2-phenylethyl)benzimidazole, 5,6-dimethyl-7-benzoyl-2-(3-phenylpropyl)benzimidazole, 4,5-dichloro-6-n-butyl-2-(9-phenylnonyl)benzimidazole, 4-fluoro-6-formyl-2-benzylbenzimidazole, 6-carbamoyl-5-ethoxy-2-(10-phenyldecyl)benzimidazole, 5,6-dimethyl-2-{(4-methoxyphenyl)butyl}benzimidazole, 6-chloro-2-{(2-nitrophenyl)ethyl}benzimidazole, 6-carboethoxy-2-(3-bromobenzyl)benzimidazole, 4-hydroxy-2-{(4-cyanophenyl)propyl}benzimidazole, 6-dimethylamino-2-{(4-formylphenyl)propyl}benzimidazole, 6-benzoyl-2-{(4-tert-butylphenyl)ethyl}benzimidazole, 2-{(2-acethylphenyl)pentyl}benzimidazole, 6-carbamonyl-2-{(2,4-dihydroxyphenyl)ethyl}benzimidazole and the like.

These imidazole based compounds or benzimidazole-based compounds can be synthesized by using any known methods. For example, they can be obtained by heat reacting a benzamidine derivative with α-chloroketone as shown in the following reaction formula.

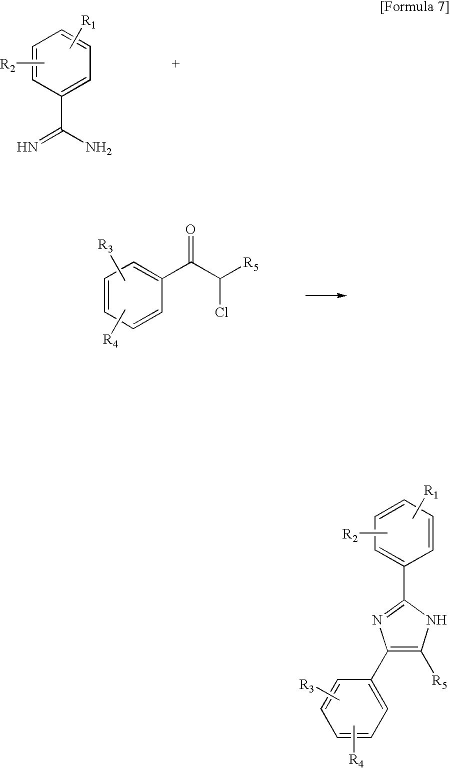

As shown in the following reaction formula, further, they can be obtained by heat reacting an orthophenyldiamine derivative with an organic acid.

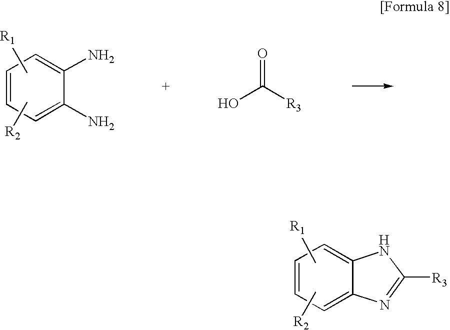

For the execution of the present invention, an imidazole-based compound and/or a benzimidazole-based compound are/is included as an essential component in a surface treatment agent in a total amount of, preferably 0.01-10%, more preferably 0.05-5%. When the total amount of the imidazole-based compound and the benzimidazole-based compound is less than 0.01%, an effective rust preventive film tends not to be formed, and when it exceeds 10%, an insoluble content tends to increase.

To the water-soluble preflux of the present invention, further, as a complex coating forming auxiliary agent, a metal compound such as copper formate, cuprous chloride, cupric chloride, copper oxalate, copper acetate, copper hydroxide, cuprous oxide, cupric oxide, copper carbonate, copper phosphate, copper sulfate, manganese formate, manganese chloride, manganese oxalate, manganese sulfate, zinc acetate, lead acetate, zinc hydride, ferrous chloride, ferric chloride, ferrous oxide, ferric oxide, copper iodide, cuprous bromide, or cupric bromide may be added. These are used alone or in combination of two ore more, and the amount added is set preferably to 0.01-10 wt % to the treatment solution, more preferably to 0.05-5 wt %. However, attention is needed for the addition of a complex forming auxiliary agent with copper because the coating may be also formed on the gold plating of a printed wiring board depending on the condition to cause discoloration of the gold plating.

The combined use of a buffer solution containing a metal ion using the above metal compound is also preferred. Examples of a typical base therefor include ammonia, diethylamine, triethylamine, diethanolamine, triethanolamine, monoethanolamine, dimethylethanolamine, diethylethanolamine, isopropylethanolamine, sodium hydroxide, potassium hydroxide and the like.

In order to further improve the soldering characteristic, for example, a halide such as potassium iodide, potassium bromide, zinc iodide, zinc bromide, propionic bromide or iodopropionic acid may be added to the water-soluble preflux of the present invention. These are used alone or in combination of two or more, and the amount added is set preferably at 0.01-10 wt % to the treatment solution, more preferably to 0.05-5 wt %.

Based on this, at least one of the above-mentioned metallic compounds and halides (or a buffer solution containing at least one metal ion of the above-mentioned metallic compounds) may be included in a water-soluble preflux containing at least one compound selected from the group consisting of the imidazole-based compound and the benzimidazole-based compound and an organic acid having a boiling point of 170° C. or higher.

To form a rust preventive film by applying the water-soluble preflux of the present invention for rust preventing treatment, a printed circuit board to be treated is subjected to a pre-treatment process for polishing, degreasing, acid pickling and washing the surface of the copper layer thereof, and then dipped in the water-soluble preflux at 10-60° C. for several seconds to several tens minutes, preferably at 20-50° C. for 5 seconds to 1 hour, preferably for 10 seconds to 10 minutes. The imidazole based compound of the present invention is thus adhered to the copper layer, but the adhesion amount increases as the treatment temperature is raised and the processing time is extended. At this time, use of ultrasonic waves is further preferable. Other application means, for example, atomization, brush application, roller application, and the like are also usable. The thus-obtained rust preventive film enables molten solder to satisfactorily wet and spread over the soldering land which is deteriorated by high-temperature heating in double-face mounting or the like.

To the printed circuit board with the rust preventive film formed by application of the water-soluble preflux, a solution of a thermoplastic resin excellent in heat resistance consisting of a rosin derivative, a terpene phenolic resin or the like dissolved in a solvent may be uniformly applied by use of a roll coater or the like to improve the heat resistance.

To produce the printed circuit board of the present invention, for example, the following processes are carried out.
(1) A process for forming a circuit pattern consisting of a predetermined circuit wiring having a soldering land for soldering a chip part on a board consisting of a copper-clad lamination by etching, and covering it with a solder resist except the soldering land.
(2) A pretreatment process for polishing, degreasing, acid pickling (soft etching), and washing the copper surface of the circuit pattern.
(3) A process for applying the water-soluble preflux containing, as essential components, the imidazole-based compound and/or the benzimidazole-based compound and the organic acid having a boiling point of 170° C. or higher to the copper surface of the exposed soldering land followed by drying.

A solder paste (containing solder powder and a flux) is applied to the above-mentioned soldering land after application of a post-flux to the resulting printed circuit board or without application thereof, and the electrodes of the chip part are reflow-soldered.

### EXAMPLES

Preferred embodiments of the present invention will be described according to the following examples.

### Example 1

To 100 g of 15% aqueous solution of levulinic acid, 0.3 g of 5-hexyl-2,4-diphenyl-1H-imidazole and 0.1 g of zinc iodide were dissolved, and the resulting solution was pH-adjusted by use of aqueous ammonia to prepare a water-soluble preflux.

### Example 2

To 100 g of 15% aqueous solution of methoxy acetic acid, 0.3 g of 5-(2-bromobutyl)-2,4-diphenyl-1H-imidazole and 0.1 g of zinc iodide were dissolved, and the resulting solution was pH-adjusted by use of aqueous ammonia to prepare a water-soluble preflux.

### Example 3

To 100 g of 15% aqueous solution of levulinic acid, 0.3 g of 2,4-diphenyl-1H-imidazole and 0.1 g of zinc iodide were dissolved, and the resulting solution was pH-adjusted by use of aqueous ammonia to prepare a water-soluble preflux.

### Example 4

To 100 g of 15% aqueous solution of methoxy acetic acid, 0.3 g of 2,4-diphenyl-1H-imidazole and 0.1 g of zinc iodide were dissolved, and the resulting solution was pH-adjusted by use of aqueous ammonia to prepare a water-soluble preflux.

### Example 5

To 100 g of 15% aqueous solution of levulinic acid, 0.3 g of 2-benzylbenzimidazole and 0.1 g of zinc iodide were dissolved, and the resulting solution was pH-adjusted by use of aqueous ammonia to prepare a water-soluble preflux.

### Example 6

To 100 g of 15% aqueous solution of methoxy acetic acid, 0.3 g of 2-benzylbenzimidazole and 0.1 g of zinc iodide were dissolved, and the resulting solution was pH-adjusted by use of aqueous mmonia to prepare a water-soluble preflux.

### Example 7

To 100 g of 15% aqueous solution of levulinic acid, 0.3 g of 2-naphthalene-1-yl-methyl-benzimidazole and 0.1 g of zinc iodide were dissolved, and the resulting solution was pH-adjusted by use of aqueous ammonia to prepare a water-soluble preflux.

### Example 8

To 100 g of 15% aqueous solution of methoxy acid, 0.3 g of 2-naphthalene-1-yl-methyl-benzimidazole and 0.1 g of zinc iodide were dissolved, and the resulting solution was pH-adjusted by use of aqueous ammonia to prepare a water-soluble preflux.

### Comparative Example 1

To 100 g of 15% aqueous solution of acetic acid, 0.3 g of 5-hexyl-2,4-diphenyl-1H-imidazole and 0.1 g of zinc iodide were dissolved, and the resulting solution was pH-adjusted by use of aqueous ammonia to prepare a water-soluble preflux.

### Comparative Example 2

To 100 g of 15% aqueous solution of acetic acid, 0.3 g of 2,4-diphenyl-1H-imidazole and 0.1 g of zinc iodide were dissolved, and the resulting solution was pH-adjusted by use of aqueous ammonia to prepare a water-soluble preflux.

### Comparative Example 3

To 100 g of 15% aqueous solution of acetic acid, 0.3 g of 2-benzylbenzimidazole and 0.1 g of zinc iodide were dissolved, and the resulting solution was pH-adjusted by use of aqueous ammonia to prepare a water-soluble preflux.

### Comparative Example 4

To 100 g of 15% aqueous solution of acetic acid, 0.3 g of 2-naphthalene-1-yl-methyl-benzimidazole and 0.1 g of zinc iodide were dissolved, and the resulting solution was pH-adjusted by use of aqueous ammonia to prepare a water-soluble preflux.

An evaluation board having a rust preventive film formed according to the method described below was used to perform a characteristic evaluation. The results are shown below. The following test method was used as the method of characteristic evaluation.

(Forming Method of Coating)

An evaluation board the copper foil surface of which is preliminarily purified with a soft etching agent (Commercial name: SE-30M manufactured by TAMURA KAKEN Corporation) was dipped in each of the water-soluble prefluxes described in the examples, which were heated to 40° C., for a predetermined time, followed by water-washing and drying, and a rust preventive film was formed on the surface of the evaluation board in a thickness of 0.2 μm.

(Measurement of Scattering Amount of Organic Acid)

Each of the adjusted water-soluble prefluxes was heated to 40° C. to condense the chemical solution.

The condensation amount of the chemical solution and the organic acid amount in the solution were determined to calculate the evaporation amount of the organic acid to the atmosphere. The measurement result is shown in Table 1.

TABLE 1
Comparison of amounts of scattered organic acids from
Water soluble preflux

| | |
|---|---|
| Concentrated | Amount of scattered organic acids |

| amount | 0% | 10% | 20% | 30% | 40% | 50% |
|---|---|---|---|---|---|---|
| Example 1 | 0% | 0% | 0% | 0% | 0% | 0% |
| Example 2 | 0% | 0% | 0% | 0% | 0% | 0% |
| Example 3 | 0% | 0% | 0% | 0% | 0% | 0% |
| Example 4 | 0% | 0% | 0% | 0% | 0% | 0% |
| Example 5 | 0% | 0% | 0% | 0% | 0% | 0% |
| Example 6 | 0% | 0% | 0% | 0% | 0% | 0% |
| Example 7 | 0% | 0% | 0% | 0% | 0% | 0% |
| Example 8 | 0% | 0% | 0% | 0% | 0% | 0% |
| Comparative | 0% | 6% | 11% | 15% | 19% | 23% |
| Example 1 | | | | | | |
| Comparative | 0% | 6% | 11% | 15% | 19% | 23% |
| Example 2 | | | | | | |
| Comparative | 0% | 6% | 11% | 15% | 19% | 23% |
| Example 3 | | | | | | |
| Comparative | 0% | 6% | 11% | 15% | 19% | 23% |
| Example 4 | | | | | | |

(Heating Deterioration Treatment)

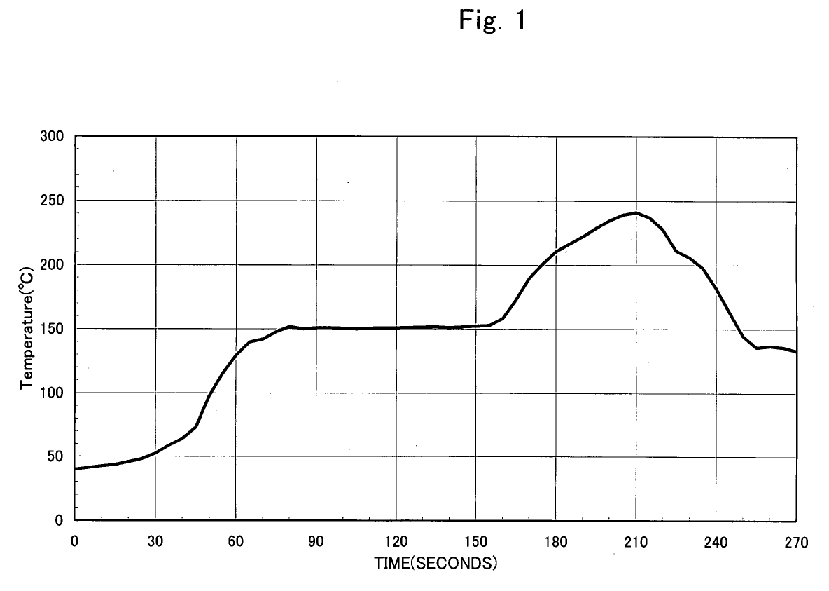

An air reflow furnace having a temperature profile shown in FIG. 1 was used for the heat resistance test of the water-soluble preflux coatings. A plurality of reflow treatments were carried out, whereby heating deterioration treatment of the printed circuit board was performed.

(Humidification Deterioration Treatment)

The humidification deteriorating property of the water-soluble preflux coatings was tested by putting them in a constant-temperature, constant-humidity bath at 40° C. and 90% R.H. for 96 hours.

(Odor)

An adjusted aqueous solution of each water-soluble preflux was heated to 40° C. to confirm generation of a pungent order. The evaluation result is shown in Table 2.

(Solder Spreadability Test 1)

As a test board, a JIS 2 type comb-shaped board with a rust preventive film formed by the method described above was used.

The test board with a coating formed thereon was heated 0-3 times under the above reflow condition, one-character printing of a solder paste (Commercial name: RMA-010NFP manufactured by TAMURA KAKEN Corporation) was carried out by use of a metal mask having an opening width of 0.635 mm and a thickness of 200 μm followed by reflow heating, and the spread length of the solder was measured. The larger spread length of the solder shows the higher wettability of the solder. The evaluation result of each water-soluble preflux is shown in Table 2.

(Solder Spreadability Test 2)

As a test board, a JIS 2-type comb-shaped board was used, and a rust preventive film was formed thereon by the method described above.

The test board with a coating was subjected to humidification deterioration treatment, and then heated 0-3 times under the above reflow condition. Thereafter, one-character printing of a solder paste (Commercial name: RMA-010NFP manufactured by TAMURA KAKEN Corporation) was carried out by use of a metal mask having an opening width 0.635 mm and a thickness of 200 μm followed by reflow heating treatment, and the spread length of the solder was measured. The larger spread length of the solder shows the higher wettability of the solder. The evaluation result of each water-soluble preflux is shown in Table 2.

TABLE 2
Comparison of property of water soluble preflux

| | | Solder | | | | Solder | | | |
|---|---|---|---|---|---|---|---|---|---|
| | | spreadability test 1 | | | | spreadability test 2 | | | |
| | | Number of reflow | | | | Number of reflow | | | |
| | Odor | 0 | 1 | 2 | 3 | 0 | 1 | 2 | 3 |
| Example 1 | No irritating odor | 6 mm | 6 mm | 5 mm | 3 mm | 6 mm | 5 mm | 4 mm | 3 mm |
| Example 2 | No irritating odor | 6 mm | 6 mm | 5 mm | 3 mm | 6 mm | 5 mm | 4 mm | 3 mm |
| Example 3 | No irritating odor | 7 mm | 7 mm | 6 mm | 4 mm | 6 mm | 6 mm | 5 mm | 3 mm |
| Example 4 | No irritating odor | 7 mm | 7 mm | 6 mm | 4 mm | 6 mm | 6 mm | 5 mm | 3 mm |
| Example 5 | No irritating odor | 6 mm | 6 mm | 5 mm | 3 mm | 6 mm | 5 mm | 4 mm | 3 mm |
| Example 6 | No irritating odor | 6 mm | 6 mm | 5 mm | 3 mm | 6 mm | 5 mm | 4 mm | 3 mm |
| Example 7 | No irritating odor | 7 mm | 7 mm | 6 mm | 4 mm | 6 mm | 6 mm | 5 mm | 3 mm |
| Example 8 | No irritating odor | 7 mm | 7 mm | 6 mm | 4 mm | 6 mm | 6 mm | 5 mm | 3 mm |
| Comparative | Irritating odor | 6 mm | 6 mm | 5 mm | 3 mm | 6 mm | 5 mm | 4 mm | 3 mm |
| Example 1 | | | | | | | | | |
| Comparative | Irritating odor | 7 mm | 7 mm | 6 mm | 4 mm | 6 mm | 6 mm | 5 mm | 3 mm |
| Example 2 | | | | | | | | | |
| Comparative | Irritating odor | 6 mm | 6 mm | 5 mm | 3 mm | 6 mm | 5 mm | 4 mm | 3 mm |
| Example 3 | | | | | | | | | |
| Comparative | Irritating odor | 7 mm | 7 mm | 6 mm | 4 mm | 6 mm | 6 mm | 5 mm | 3 mm |
| Example 4 | | | | | | | | | |

(Through-Hole Solder Creeping Property Test 1)

As a test board, a board having 360 through-holes having inside diameters of 0.6-1.0 mm, with a rust preventive film formed thereon by the method described above, was used. After test board with a coating thereon was heated 0-3 times under the above reflow condition, a post-flux (Commercial Name: CF-110VH-2A manufactured by TAMURA KAKEN Corporation) was applied thereto, and soldering treatment was performed by use of a flow soldering device. The ratio of the number of through-holes in which the solder crept to the upper part thereof was measured. The evaluation result of each water-soluble preflux is shown in Table 3.

(Through-Hole Solder Creeping Property Test 2)

As a test board, a board having 360 through-holes having inner diameters of 0.6-1.0 mm, with a rust preventive film formed thereon by the method described above, was used. The test board with a coating formed thereon was subjected to the humidification deterioration treatment, and heated 0-3 times under the above reflow condition. Thereafter, a post-flux (Commercial Name: CF-110VH-2A manufactured by TAMURA KAKEN Corporation) was applied thereto, and soldering treatment was performed by use of a flow soldering device. The ratio of the number of through-holes in which the solder crept to the upper part thereof was measured. The evaluation result of each water-soluble preflux is shown in Table 3.

TABLE 3
Comparison of property of water soluble preflux

| | Through hole | | | | Through hole | | | |
|---|---|---|---|---|---|---|---|---|
| | solder creeping test 1 | | | | solder creeping test 2 | | | |
| | Number of reflow | | | | Number of reflow | | | |
| | 0 | 1 | 2 | 3 | 0 | 1 | 2 | 3 |
| Example 1 | 100% | 100% | 100% | 100% | 100% | 100% | 100% | 100% |
| Example 2 | 100% | 100% | 100% | 100% | 100% | 100% | 100% | 100% |
| Example 3 | 100% | 100% | 100% | 100% | 100% | 100% | 100% | 100% |
| Example 4 | 100% | 100% | 100% | 100% | 100% | 100% | 100% | 100% |
| Example 5 | 100% | 100% | 100% | 100% | 100% | 100% | 100% | 100% |
| Example 6 | 100% | 100% | 100% | 100% | 100% | 100% | 100% | 100% |
| Example 7 | 100% | 100% | 100% | 100% | 100% | 100% | 100% | 100% |
| Example 8 | 100% | 100% | 100% | 100% | 100% | 100% | 100% | 100% |
| Comparative | 100% | 100% | 100% | 100% | 100% | 100% | 100% | 100% |
| Example 1 | | | | | | | | |
| Comparative | 100% | 100% | 100% | 100% | 100% | 100% | 100% | 100% |
| Example 2 | | | | | | | | |
| Comparative | 100% | 100% | 100% | 100% | 100% | 100% | 100% | 100% |
| Example 3 | | | | | | | | |
| Comparative | 100% | 100% | 100% | 100% | 100% | 100% | 100% | 100% |
| Example 4 | | | | | | | | |

(Water-Soluble Preflux Storage Stability Test)

A prepared aqueous solution of each water-soluble preflux was stored at 0° C., and the deposition of effective components was measured. The evaluation result of each water-soluble preflux is shown in Table 4.

TABLE 4
Comparison of property of water soluble preflux

| | Test of stability of preservation |
|---|---|
| | Of water soluble preflux |
| Example 1 | Not changed |
| Example 2 | Not changed |
| Example 3 | Not changed |
| Example 4 | Not changed |
| Example 5 | Not changed |
| Example 6 | Not changed |
| Example 7 | Not changed |
| Example 8 | Not changed |
| Comparative | Not changed |
| Example 1 | |
| Comparative | Not changed |
| Example 2 | |
| Comparative | Not changed |
| Example 3 | |
| Comparative | Not changed |
| Example 4 | |

As described above, an imidazole based compound or benzimidazole based compound is used in combination with an organic acid having a boiling point of 170° C. or higher, whereby the problems of odor, deterioration of working environments, and scattering of an organic acid compound to the atmosphere can be solved. Further, the fluctuation of the solution composition is reduced, whereby the fluctuation of the film physical property can be prevented. Moreover, the loss of stability by temperature change can be successfully prevented while keeping high heat resistance and moisture resistance and excellent solderability in component mounting, and thus, a water-soluble preflux having coating characteristics comparable to the current products, a printed circuit board, and a surface treatment method for metal of the printed circuit board can be provided. Further, the same production method and usage as a conventional water-soluble preflux using an organic acid having a low boiling point can be applied.

The present invention has been explained referring to the preferred embodiments, however, the present invention is not limited to the illustrated embodiments which are given by way of examples only, and may be carried out in various modes without departing from the scope of the invention.

1. A surface treatment agent for metal comprising an aqueous solution comprising an organic acid having a boiling point of 170° C. or higher and one or more compound selected from the group consisting of an imidazole based compound and a benzimidazole based compound.

2. The surface treatment agent according to claim 1, wherein said organic acid comprising one or more organic acid selected from the group consisting of a saturated fatty acid, an unsaturated fatty acid, an alkoxy fatty acid, a hydroxy fatty acid and a keto fatty acid.

3. The surface treatment agent according to claim 1, wherein said organic acid is levulinic acid or methoxy acetic acid.

4. The surface treatment agent according to claim 1, wherein the content of said organic acid is within the range of from 1 wt % to 40 wt %.

5. The surface treatment agent according to claim 1, wherein the total content of said imidazole based compound and said benzimidazole based compound is 0.01-10 wt %.

6. A printed circuit board comprising a rust preventive film formed by applying a surface treatment agent according to claim 1.

7. A surface treatment method for metal of a printed circuit board, comprising applying a surface treatment agent according to claim 1 onto a metal film of said printed circuit board to form a rust preventive film.
